(19) United States
(12) Patent Application Publication
(10) Pub. No.: US 2024/0112909 A1
(43) Pub. Date: Apr. 4, 2024

(54) NITRIDE SEMICONDUCTOR EPITAXIAL SUBSTRATE, METHOD FOR PRODUCING SAME, AND NITRIDE SEMICONDUCTOR DEVICE

(71) Applicant: Panasonic Intellectual Property Management Co., Ltd., Osaka (JP)

(72) Inventors: Hisayoshi MATSUO, Osaka (JP); Hideyuki OKITA, Osaka (JP); Masahiro HIKITA, Hyogo (JP); Yasuhiro UEMOTO, Shiga (JP); Manabu YANAGIHARA, Osaka (JP)

(21) Appl. No.: 18/264,202

(22) PCT Filed: Jan. 4, 2022
(86) PCT No.: PCT/JP2022/000030

§ 371 Date: Aug. 3, 2023

(30) Foreign Application Priority Data
Feb. 22, 2021 (JP) 2021-025907

(51) Int. Cl. H01L 21/02; C30B 25/18; C30B 29/40; H01L 29/20; H01L 29/778

(52) U.S. Cl. CPC H01L 21/02505; C30B 25/183; C30B 29/406; H01L 21/02381; H01L 21/02458; H01L 21/0254; H01L 21/0262; H01L 29/2003; H01L 29/7786

(57) ABSTRACT

A nitride semiconductor epitaxial substrate includes: a Si substrate; a nitride semiconductor epitaxial layer disposed above the Si substrate; and a mixed crystal layer disposed between the Si substrate and the nitride semiconductor epitaxial layer, and containing Si and a group III metal element, the mixed crystal layer containing a high concentration of C. The mixed crystal layer has a concentration of at least 1.0×10⁺²¹ cm⁻³, and a transition metal element concentration of at most 5.0×10⁺¹⁶ cm⁻³.

### CROSS-REFERENCE OF RELATED APPLICATIONS

This application is the U.S. National Phase under 35 U.S.C. § 371 of International Patent Application No. PCT/JP2022/000030, filed on Jan. 4, 2022, which in turn claims the benefit of Japanese Patent Application No. 2021-025907, filed on Feb. 22, 2021, the entire disclosures of which Applications are incorporated by reference herein.

### TECHNICAL FIELD

The present disclosure relates to a nitride semiconductor epitaxial substrate including a Si substrate, a method for producing the nitride semiconductor epitaxial substrate, and a nitride semiconductor device typified by a field-effect transistor produced using the nitride semiconductor epitaxial substrate.

### BACKGROUND ART

Nitride semiconductors have a larger bandgap than Si semiconductors or compound semiconductors such as GaAs, and have high dielectric breakdown field and high saturation lift speed. The nitride semiconductors have been applied to electronic devices such as power devices that withstand high voltage and high-speed, high-output transistors.

Sapphire substrates, SiC substrates, Si substrates, and the like are used as substrates for growing nitride semiconductors applied to electronic devices. A technique for producing Si substrates with large diameters has been established, and the Si substrates are excellent in cost. Accordingly, the Si substrates are most advantageous for mass production.

However, the Si substrate has a large lattice mismatch with and a large thermal expansion coefficient difference from the nitride semiconductor compared to other substrates. Hence, it is difficult to form a nitride semiconductor epitaxial layer with excellent crystallinity above the Si substrate. Since the crystallinity of a nitride semiconductor epitaxial layer greatly affects the characteristics and reliability of electronic devices, forming a nitride semiconductor epitaxial layer with excellent crystallinity above a Si substrate is a major issue.

Regarding the formation of the nitride semiconductor epitaxial layer above the Si substrate, introduction of a nitride semiconductor layer structure and a buffer layer are being studied. For example, in Patent Literature (PTL) 1 and PTL 2, the initial layer of a nitride semiconductor epitaxial layer formed above a Si substrate is doped with a high concentration of C or Fe, so that leakage current is reduced and high-frequency characteristics are improved. In PTL 3, by forming a nitride semiconductor epitaxial layer above a semiconductor substrate in which a single crystal SiC film is disposed on a surface of a Si substrate, crystallinity of the nitride semiconductor epitaxial layer is improved.

### CITATION LIST

### Patent Literature

[PTL 1] Japanese Unexamined Patent Application Publication No. 2018-46207
[PTL 2] Japanese Unexamined Patent Application Publication No. 2011-166067
[PTL 3] Japanese Patent No. 6156833

### SUMMARY OF INVENTION

### Technical Problem

However, in the semiconductor substrates disclosed in PTL 1 and PTL 2, the crystallinity of the nitride semiconductor epitaxial layer is approximately the same or lower than when the initial layer of the nitride semiconductor epitaxial layer is not doped with C or Fe. In other words, there remains a problem in increasing the quality of the nitride semiconductor epitaxial layer.

In the semiconductor substrate disclosed in PTL 3, it is difficult to increase the quality of the single crystal SiC disposed above the Si substrate, and the cost will increase greatly.

In view of the above problems, an object of the present disclosure is to achieve a nitride semiconductor epitaxial substrate in which a layer with excellent crystallinity is disposed above a Si substrate, a method for producing the nitride semiconductor epitaxial substrate, and a nitride semiconductor device including the nitride semiconductor epitaxial substrate.

### Solution to Problem

In order to solve the above problems, a nitride semiconductor epitaxial substrate according to one aspect of the present disclosure includes: a Si substrate; a nitride semiconductor epitaxial layer disposed above the Si substrate; and a mixed crystal layer disposed between the Si substrate and the nitride semiconductor epitaxial layer, the mixed crystal layer containing Si and a group III metal element, the mixed crystal layer containing a high concentration of C, in which a concentration of the C in the mixed crystal layer is at least 1.0×10⁺²¹ cm⁻³, and the mixed crystal layer contains a transition metal element at a concentration of at most 5.0×10⁺¹⁶ cm⁻³.

A nitride semiconductor epitaxial substrate according to one aspect of the present disclosure includes: a Si substrate; a heterostructure epitaxial layer which includes a nitride semiconductor epitaxial layer disposed above the Si substrate; and a mixed crystal layer disposed between the Si substrate and the nitride semiconductor epitaxial layer, the mixed crystal layer containing Si and a group III metal element, the mixed crystal layer containing a high concentration of C, in which a concentration of the C in the mixed crystal layer is higher than a concentration of C in each of layers included in the heterostructure epitaxial layer, and the mixed crystal layer contains a transition metal element at a concentration of at most 5.0×10⁺¹⁶ cm⁻³.

A nitride semiconductor device according to one aspect of the present disclosure is formed using the nitride semiconductor epitaxial substrate.

A method of producing a nitride semiconductor epitaxial substrate according to one aspect of the present disclosure includes: increasing a temperature of a Si substrate to 500° C. or higher; supplying a C material to a surface of the Si substrate; growing a first nitride semiconductor layer above the Si substrate by crystal growth; maintaining the temperature of the Si substrate and a temperature of the first nitride semiconductor layer at 900° C. or higher, and diffusing a group III metal element from the first nitride semiconductor layer to the Si substrate; and growing a second nitride semiconductor layer above the first nitride semiconductor layer by crystal growth.

### Advantageous Effects of Invention

The present disclosure provides, for example, a nitride semiconductor epitaxial substrate in which a layer with excellent crystallinity is disposed above a Si substrate.

### BRIEF DESCRIPTION OF DRAWINGS

FIG. 1 is a cross-sectional view of a nitride semiconductor epitaxial substrate according to Embodiment 1 of the present disclosure.

FIG. 2 is a schematic diagram of C concentration, Fe concentration, and Si concentration in each structural component according to Embodiment 1 of the present disclosure.

FIG. 3 illustrates results of evaluations of dependence of concentrations of C and Fe, which is a transition metal element, in a mixed crystal layer on crystallinity of an AlN layer.

FIG. 4 illustrates analytical results of secondary ion mass of C concentration and Si concentration in each structural component according to Embodiment 1 of the present disclosure.

FIG. 5 is a cross-sectional view of a nitride semiconductor epitaxial substrate according to Variation 1 of Embodiment 1 of the present disclosure.

FIG. 6A is a schematic diagram of C concentration and Si concentration in each structural component according to Variation 1 of Embodiment 1 of the present disclosure.

FIG. 6B is a cross-sectional view of a nitride semiconductor epitaxial substrate according to Variation 2 of Embodiment 1 of the present disclosure.

FIG. 7 is a cross-sectional view of a nitride semiconductor heterostructure epitaxial substrate according to Embodiment 2 of the present disclosure.

FIG. 8 illustrates results of evaluations of influences of C concentration in a mixed crystal layer and C concentration in a heterostructure epitaxial layer on crystallinity of a GaN channel layer.

FIG. 9 is a cross-sectional view of a nitride semiconductor device according to Embodiment 3 of the present disclosure.

### DESCRIPTION OF EMBODIMENTS

Hereinafter, embodiments of the present disclosure will be described in detail with reference to the drawings. Each of the following embodiments describes a general or specific example. The numerical values, shapes, materials, structural components, the arrangement and connection of the structural components, etc. shown in the following embodiments are mere examples, and therefore do not limit the present disclosure. Among the structural components in the following embodiments, those not recited in any of the independent claims are described as optional structural components.

The figures are represented schematically and are not necessarily precise illustrations. In the figures, elements that are essentially the same share like reference signs, and duplicate description thereof is omitted or simplified.

In the following embodiments, the term “above” does not simply refer to the upward direction (vertically upward) in absolute space. In addition, the term “above” encompasses not only the case where two structural components are disposed spaced apart from each other with another structural component interposed between the two structural components, but also the case where two structural components are disposed closely adhering to each other and making contact with each other.

### Embodiment 1

[Configuration]

First, a configuration of nitride semiconductor epitaxial substrate 100 according to the present embodiment will be described.

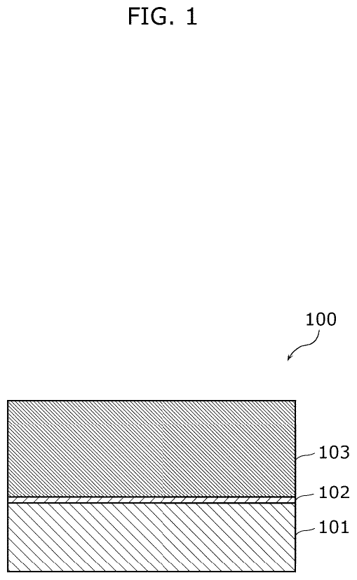

FIG. 1 is a cross-sectional view of nitride semiconductor epitaxial substrate 100 according to Embodiment 1 of the present disclosure. As illustrated in FIG. 1, in nitride semiconductor epitaxial substrate 100 according to the present embodiment, a nitride semiconductor epitaxial layer, for example, AlN layer 103 is epitaxially grown above Si substrate 101 via mixed crystal layer 102 which contains Al, Si, and C as main components. In other words, nitride semiconductor epitaxial substrate 100 according to the present embodiment includes Si substrate 101, mixed crystal layer 102 disposed above Si substrate 101, and a nitride semiconductor epitaxial layer (here, AlN layer 103) disposed above mixed crystal layer 102. In other words, mixed crystal layer 102 is disposed between Si substrate 101 and AlN layer 103 and in contact with Si substrate 101 and AlN layer 103.

Si substrate 101 is a substrate made of Si.

Mixed crystal layer 102 is a layer containing a group III metal element (here, Al) and Si, and further containing a high concentration of C. Moreover, the terms “main component” and “mainly contain” mean that in mixed crystal layer 102, the percentage of the total element amount of the group III metal element, Si, and C to the total element amount in mixed crystal layer 102 is, for example, at least 50%. Note that the percentage may refer to at least 90%.

Here, the constituent element of mixed crystal layer 102 is not limited to Al, which is an example of the group III metal element, but may be, instead of Al, other group III metal elements (for example, Ga and In), or may include one or more of these elements.

Mixed crystal layer 102 is a polycrystalline layer containing Al, Si and C as main components, and the lattice constant of mixed crystal layer 102 is closer to the lattice constant of AlN than to the lattice constant of Si. Accordingly, by epitaxially growing AlN layer 103 above mixed crystal layer 102 with this polycrystalline layer (mixed crystal layer 102) as a buffer layer, a nitride semiconductor epitaxial layer (AlN layer 103) having excellent crystallinity as compared with the conventional one can be achieved.

Mixed crystal layer 102 is formed in a growth furnace for forming AlN layer 103 which is a nitride semiconductor epitaxial layer. Accordingly, the group III metal element as a constituent element of mixed crystal layer 102 may be the same as one or more of the group III metal elements as constituent elements of the nitride semiconductor epitaxial layer formed above mixed crystal layer 102. In other words, in the present embodiment, the group III metal element of mixed crystal layer 102 is identical to the group III metal element of the nitride semiconductor epitaxial layer. With this, nitride semiconductor epitaxial substrate 100 according to the present embodiment can be achieved without greatly increasing the number of processes.

The group III metal element of AlN layer 103, which is a nitride semiconductor epitaxial layer, is not limited to Al, but may be any other group III metal elements (for example, Ga and In) instead of Al, or may include one or more elements of those group III metal elements. However, in order to prevent abnormal growth due to reaction between Ga and Si, the group III metal element in the portion of AlN layer 103 that contacts mixed crystal layer 102 may be Al only. Note that mixed crystal layer 102 may contain N or O present on the surface of Si substrate 101 as a constituent element of an oxide film or nitride film.

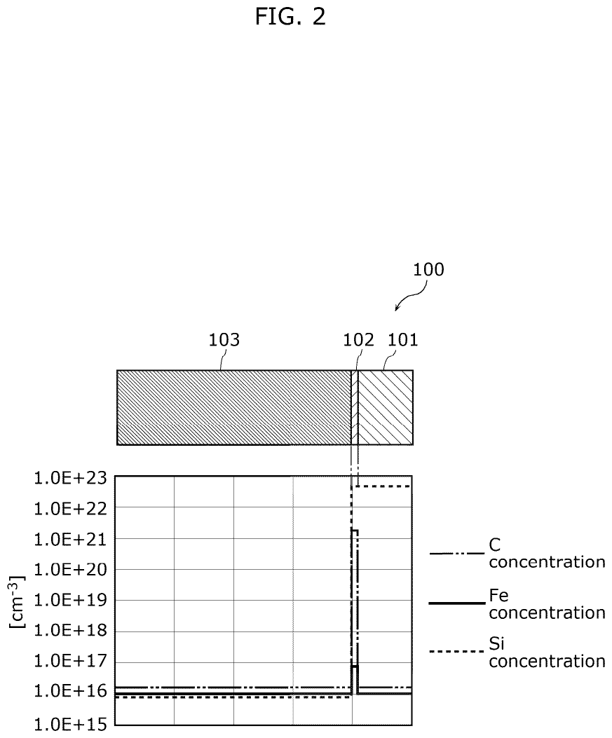

FIG. 2 is a schematic diagram of C concentration, Fe concentration, and Si concentration in each structural component according to Embodiment 1 of the present disclosure. As illustrated in FIG. 2, mixed crystal layer 102 has a C concentration of at least 1.0×10⁺²¹ cm⁻³ and a Fe concentration of at most 5.0×10⁺¹⁶ cm⁻³. The C concentration in mixed crystal layer 102 is at most 1.0×10⁺²² cm⁻³. Note that the C concentration in mixed crystal layer 102 is defined as the highest value of the C concentration in mixed crystal layer 102. Moreover, in the present embodiment, mixed crystal layer 102 contains a high concentration of C. Here, the term “high concentration” refers to that the C concentration is at least 1.0×10⁺²¹ cm⁻³ as described above. In such a manner, mixed crystal layer 102 according to the present embodiment contains the group III metal element (here, Al), Si, C, and transition metal element (here, Fe). In addition, the transition metal element contained in mixed crystal layer 102 may be referred to as the transition metal element in mixed crystal layer 102.

The transition metal element contained in mixed crystal layer 102 is not limited to Fe. The transition metal element contained in mixed crystal layer 102 may include any one of Cr, Cu, Ni, Mn, or Co, which are transition metal elements that may be mixed in a MOCVD furnace. The MOCVD furnace is an example of a growth furnace for forming AlN layer 103. The term MOCVD refers to metal organic chemical vapor deposition. By configuring mixed crystal layer 102 in such a manner, the stability of the crystallinity of AlN layer 103 can be ensured. In other words, in the present embodiment, the transition metal element in mixed crystal layer 102 is at least one of Fe, Cr, Cu, Ni, Mn, or Co, so that the stability of the crystallinity of AlN layer 103 can be ensured.

Moreover, when the transition metal element contained in mixed crystal layer 102 is at least one of Fe, Cr, Cu, Ni, Mn or Co, the concentration of each of the transition metal elements is set to at most 5.0×10⁺¹⁶ cm⁻³, so that the stability of the crystallinity of AlN layer 103 can be further ensured. As an example, when mixed crystal layer 102 according to the present embodiment contains Fe described above and Cr which is a transition metal element, the Fe concentration is at most 5.0×10⁺¹⁶ cm⁻³, and the Cr concentration is also at most 5.0×10⁺¹⁶ cm⁻³. In other words, when mixed crystal layer 102 contains one kind of transition metal element, the concentration of the one transition metal element is at most 5.0×10⁺¹⁶ cm⁻³, and when mixed crystal layer 102 contains two or more kinds of transition metal elements, each of the concentrations of the two or more kinds of transition metal elements is at most 5.0×10⁺¹⁶ cm⁻³. As described, the transition metal element in mixed crystal layer 102 is at least one of Fe, Cr, Cu, Ni, Mn, or Co, and the concentration of each of the transition metal elements is at most 5.0×10⁺¹⁶ cm⁻³. With this, the stability of the crystallinity of AlN layer 103 can be further ensured. The definitions of the values of the C concentration and the transition metal elements including Fe in mixed crystal layer 102 will be described below.

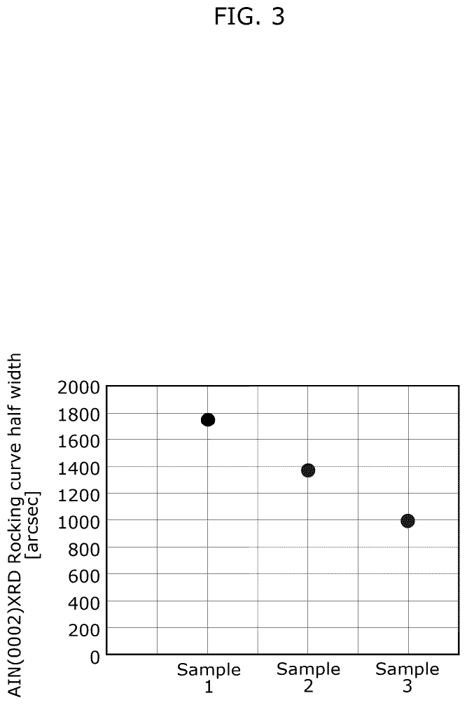

Since mixed crystal layer 102 is formed by supplying the C material and Al material to the front surface of Si substrate 101, insufficient supply of these materials is expected to lead to insufficient contribution as a buffer layer. In addition, it is considered that the concentration of the transition metal element in mixed crystal layer 102 also influences the crystal quality of AlN layer 103. This influence will be described with reference to FIG. 3. FIG. 3 illustrates results of evaluations of the dependence of the concentrations of C and Fe, which is a transition metal element, in the mixed crystal layer on the crystallinity of the AlN layer. Here, the crystallinity of samples 1, 2, and 3 were evaluated.

Sample 1 is a nitride semiconductor epitaxial substrate according to Comparative Example 1. Sample 1 includes a configuration identical to the configuration of nitride semiconductor epitaxial substrate 100 according to the present embodiment, except that the C concentration in the mixed crystal layer included in Sample 1 is different from the C concentration in mixed crystal layer 102 according to the present embodiment. In a similar manner, Sample 2 is a nitride semiconductor epitaxial substrate according to Comparative Example 2. Sample 2 includes a configuration identical to the configuration of nitride semiconductor epitaxial substrate 100 according to the present embodiment, except that the Fe concentration in the mixed crystal layer included in Sample 2 is different from the Fe concentration in mixed crystal layer 102 according to the present embodiment. Sample 3 refers to nitride semiconductor epitaxial substrate 100 according to the present embodiment.

The crystallinity of each of the AlN layers of Samples 1 and 2 and AlN layer 103 of Sample 3 was evaluated by the half width of the XRD rocking curve of the (0002) plane. XRD refers to X-ray diffraction. The evaluation results of Sample 1 and Sample 2 in FIG. 3 are examples of evaluation results of C concentration dependence in mixed crystal layer 102. In other words, by comparing Sample 1 and Sample 2 in FIG. 3, the influences of the C concentration in the mixed crystal layer on the crystallinity of the AlN layer are evaluated.

The C concentration in the mixed crystal layer according to Sample 1 is 1.5×10⁺¹⁸ cm⁻³, and the C concentration in the mixed crystal layer according to Sample 2 is 1.8×10⁺²¹ cm⁻³. In Sample 1, the half width of AlN (0002) was 1750 arcsec, which was the same as the conventional one, but in Sample 2, the half width of AlN (0002) was 1400 arcsec, which was improved compared to the conventional one. Moreover, Sample 3 was produced in order to confirm the dependence of the Fe concentration in the mixed crystal layer. The Fe concentration in the mixed crystal layer of Sample 2 is 1.0×10⁺¹⁷ cm⁻³, and the Fe concentration in mixed crystal layer 102 of Sample 3 is 2.0×10⁺¹⁶ cm⁻³. As can be seen from FIG. 3, the half width of AlN (0002) in Sample 3 was 1020 arcsec, which was greatly improved in comparison with Samples 1 and 2. As a result of evaluating the half width of AlN (0002) as described above, it was confirmed that crystallinity of AlN layer 103 was significantly improved when the C concentration in mixed crystal layer 102 was at least 1.0×10⁺²¹ cm⁻³ and the transition metal element concentration was at most 5.0×10⁺¹⁶ cm⁻³.

As described above, in the present embodiment, mixed crystal layer 102 has a C concentration of at least 1.0×10⁺²¹ cm⁻³, and a transition metal element concentration of at most 5.0×10⁺¹⁶ cm⁻³. Accordingly, AlN layer 103 disposed above mixed crystal layer 102 has excellent crystallinity. Nitride semiconductor epitaxial substrate 100 according to the present embodiment includes Si substrate 101 and above-described AlN layer 103 (an example of a nitride semiconductor epitaxial layer) disposed above Si substrate 101. In other words, as described in the present embodiment, nitride semiconductor epitaxial substrate 100 is achieved in which a layer with excellent crystallinity is disposed above Si substrate 101.

The amount of transition metal element in mixed crystal layer 102 here is the total amount of intentional doping using the dopant material and automatic doping from the furnace environment. Mixed crystal layer 102 is polycrystalline Al—Si—C that achieves a nitride semiconductor epitaxial layer with excellent crystallinity, and contains Al, Si and C as main components. Accordingly, the C concentration in mixed crystal layer 102 is a value smaller than 4.0×10⁺²² cm⁻³ which is the C concentration in the single crystal SiC.

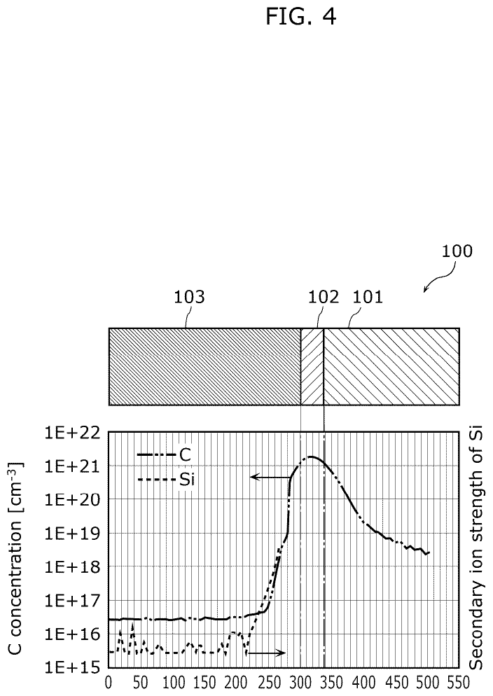

The numerical value of the C concentration in mixed crystal layer 102 will be described below. FIG. 4 illustrates results of secondary ion mass spectrometry (SIMS) of C concentration and Si concentration in each structural component according to Embodiment 1 of the present disclosure. Mixed crystal layer 102 is formed by supplying the C material to the front surface of Si substrate 101 and thermally diffusing C toward Si substrate 101. Accordingly, as illustrated in FIG. 4, the C concentration distribution in mixed crystal layer 102 is such that the C concentration is highest in the vicinity of the interface between mixed crystal layer 102 and AlN layer 103, and the C concentration is gradually decreases toward Si substrate 101. The vicinity of the interface between mixed crystal layer 102 and AlN layer 103 refers to, for example, the region of mixed crystal layer 102 within 20 nm from the interface. In other words, the C concentration distribution in mixed crystal layer 102 is such that the C concentration is higher on the nitride semiconductor epitaxial layer (AlN layer 103) side and lower on the Si substrate 101 side, and the C concentration gradually decreases from the nitride semiconductor epitaxial layer side toward the Si substrate 101 side. Note that only when explaining the C concentration distribution in mixed crystal layer 102, the term “C concentration” does not refer to the highest C concentration in mixed crystal layer 102 as described above, but refers to the C concentration at the measurement point. For other explanations, the C concentration in mixed crystal layer 102 is defined as the highest value of the C concentration in mixed crystal layer 102 as described above. The film thickness of mixed crystal layer 102 is defined as a range in which the C concentration is at least 1.0×10⁺²¹ cm⁻³. For example, in the present embodiment, the C concentration in mixed crystal layer 102 is 1.8×10⁺²¹ cm⁻³ and the thickness of mixed crystal layer 102 is 40 nm. The thickness of mixed crystal layer 102 can be controlled by the diffusion amount of C, for example, can be controlled by the thermal diffusion temperature or the thermal diffusion time. From the viewpoint of the stability of the crystallinity of AlN layer 103 which is a nitride semiconductor epitaxial layer, it is preferable that the thickness of mixed crystal layer 102 is at most 50 nm. In other words, in the present embodiment, the thickness of mixed crystal layer 102 is at most 50 nm. This ensures further stability of the crystallinity of AlN layer 103 which is a nitride semiconductor epitaxial layer.

The transition metal element in mixed crystal layer 102 also has a similar concentration distribution (that is, the concentration distribution in which the transition metal element concentration is higher on the AlN layer 103 side and lower on the Si substrate 101 side, and the transition metal element concentration gradually decreases from the AlN layer 103 side toward the Si substrate 101 side). Only when explaining the transition metal element concentration distribution in mixed crystal layer 102, the term “transition metal element concentration” refers to the transition metal element concentration at the measurement point. For other explanations, the highest value of the transition metal element concentration in mixed crystal layer 102 is defined as the transition metal element concentration in mixed crystal layer 102. Since the group III metal element in mixed crystal layer 102 is also supplied by thermal diffusion in the same manner as C, the distribution of the group III metal element concentration is highest in the vicinity of the interface with AlN layer 103 and decreases toward Si substrate 101. By forming mixed crystal layer 102 by thermal diffusion in such a manner, the process can be simplified.

[Producing Method]

Here, a producing method relating to nitride semiconductor epitaxial substrate 100 according to Embodiment 1 will be specifically described with reference to FIG. 1.

Si substrate 101 is set in a metal organic chemical vapor deposition (MOCVD) furnace, and the temperature of Si substrate 101 is increased to 500° C. or higher. After that, a C material and an Al material are supplied to the front surface of Si substrate 101 at a temperature of 500° C. or higher. Examples of the C material that can be used include trimethylaluminum (TMA) or triethylaluminum (TEA) that is an organometallic material, carbon tetrabromide (CBr₄), or propane (C₃Hs). These are materials provided in the MOCVD furnace as group III element supply sources or dopant supply sources, and the process can be simplified. TMA or TEA is used as the Al material. H₂, N₂ or a mixture thereof is used as a carrier gas and the C material and the Al material described above are supplied to the front surface of Si substrate 101. As a result, C and Al separated by the thermal decomposition reaction on the front surface of Si substrate 101 are adsorbed on the front surface of Si substrate 101. After that, by maintaining the temperature of Si substrate 101 at 900° C. or higher in an atmosphere in which NH₃ and carrier gas are supplied, C and Al supplied to the front surface of Si substrate 101 are thermally diffused from the front surface to the back surface of Si substrate 101. With this, mixed crystal layer 102 is formed which contains Al, Si, and C as main components. As described above, mixed crystal layer 102 is formed by thermal diffusion of C and Al adsorbed on the front surface of Si substrate 101. Hence, the C concentration distribution and the Al concentration distribution in mixed crystal layer 102 are such that the concentrations are the highest in the vicinity of the interface with AlN layer 103 and the concentrations decrease toward Si substrate 101. The highest value of the C concentration in mixed crystal layer 102 can be controlled by the supply amount of the C material. The concentration of the transition metal element in mixed crystal layer 102 can be controlled by, for example, autodoping control by the atmosphere in the reaction furnace such as the growth temperature, growth pressure, and carrier gas flow rate, in addition to intentional doping control by the supply amount of Cp₂Fe which is a Fe material. Note that Cp₂Fe refers to ferrocene.

After that, the temperature of Si substrate 101 is increased to the growth temperature of AlN layer 103, for example, 1000° C. or higher. Then, TMA or TEA is supplied as the Al material, NH₃ is supplied as the N material, and H₂, N₂, or a mixture thereof is supplied as a carrier gas. Through this step, AlN layer 103 is formed as a nitride semiconductor epitaxial layer.

In such a manner, the configuration according to Embodiment 1 (that is, nitride semiconductor epitaxial substrate 100) can be produced. Moreover, by sequentially forming mixed crystal layer 102 and the nitride semiconductor epitaxial layer (for example, AlN layer 103) in the MOCVD furnace, nitride semiconductor epitaxial substrate 100 according to Embodiment 1 can be achieved without greatly increasing the number of processes.

(Variation 1 of Embodiment 1)

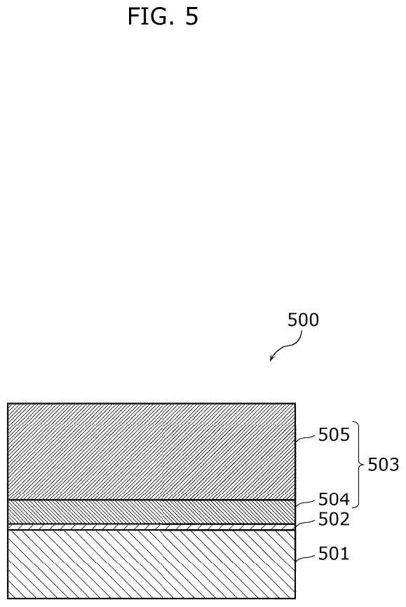

Next, nitride semiconductor epitaxial substrate 500 according to Variation 1 of Embodiment 1 will be described with reference to FIG. 5. Nitride semiconductor epitaxial substrate 500 mainly includes a configuration identical to the configuration of nitride semiconductor epitaxial substrate 100 according to Embodiment 1, except that the configuration of AlN layer 503, which is an example of a nitride semiconductor epitaxial layer, differs from AlN layer 103 according to Embodiment 1.

[Configuration]

FIG. 5 is a cross-sectional view of nitride semiconductor epitaxial substrate 500 according to Variation 1 of Embodiment 1 of the present disclosure. As illustrated in FIG. 5, in the present variation, AlN layer 503, which is an example of a nitride semiconductor epitaxial layer, is epitaxially grown above Si substrate 501 via mixed crystal layer 502 containing Al, Si and C as main components. In a similar manner to mixed crystal layer 102 according to Embodiment 1, mixed crystal layer 502 has a C concentration of at least 1.0×10⁺²¹ cm⁻³, and a Fe concentration of at most 5.0×10⁺¹⁶ cm⁻³. AlN layer 503 includes first AlN layer 504 and second AlN layer 505. The C concentration in first AlN layer 504 is higher than the C concentration of second AlN layer 505. Both the C concentration in first AlN layer 504 and the C concentration in second AlN layer 505 are at least 1.0×10⁺²¹ cm⁻³.

In other words, in the present variation, the nitride semiconductor epitaxial layer (AlN layer 503) includes a first nitride semiconductor layer (first AlN layer 504) and a second nitride semiconductor layer (second AlN layer 505). Moreover, the C concentration in the first nitride semiconductor layer is higher than the C concentration in the second nitride semiconductor layer. Moreover, in the present variation, the nitride semiconductor epitaxial layer (AlN layer 503) includes an AlN layer (first AlN layer 504) on the mixed crystal layer 502 side.

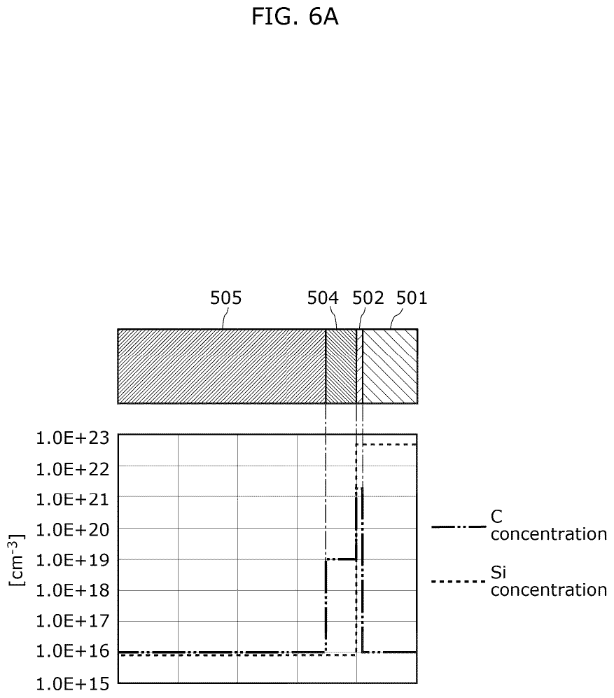

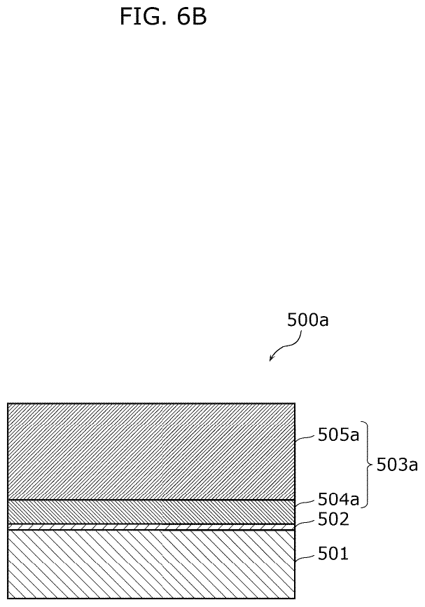

FIG. 6A is a schematic diagram of C concentration and Si concentration in each structural component according to Variation 1 of Embodiment 1 of the present disclosure. As illustrated in FIG. 6A, the C concentration in first AlN layer 504 is 1.0×10⁺¹⁹ cm⁻³ and the C concentration in second AlN layer 505 is 1.0×10⁺¹⁶ cm⁻³. For controlling the C concentrations in first AlN layer 504 and second AlN layer 505 to the above concentrations, for example, first AlN layer 504 is grown at a low temperature and second AlN layer 505 is grown at a high temperature.

In such a manner, in the present variation, the initial layer of AlN layer 503 (that is, first AlN layer 504) is made of AlN with a high concentration of C. With this, nitride semiconductor epitaxial substrate 500 is provided in which the formation of a low resistance layer at the interface between AlN layer 503 (more specifically, first AlN layer 504) and mixed crystal layer 502 is prevented. A power transistor produced using nitride semiconductor epitaxial substrate 500 is capable of reducing leakage current. Moreover, by growing the initial layer of AlN layer 503 at a low temperature, it is possible to achieve nitride semiconductor epitaxial substrate 500 with high reproducibility and excellent productivity.

[Producing Method]

Here, a producing method relating to nitride semiconductor epitaxial substrate 500 according to Variation 1 of Embodiment 1 will be specifically described with reference to FIG. 5.

Si substrate 501 is set in a MOCVD furnace, and is heated to 500° C. or higher. This corresponds to the step of increasing the temperature of Si substrate 501 to 500° C. or higher. After that, a step of supplying a C material to the front surface of Si substrate 501 is performed. More specifically, a C material and an Al material are supplied to the front surface of Si substrate 501 at a temperature of 500° C. or higher. Examples of the C material that can be used include TMA, TEA, CBr₄ and C₃Hs. TMA or TEA is used as the Al material. H₂, N₂ or a mixture thereof is used as a carrier gas to supply the above-mentioned C material and Al material to the front surface of Si substrate 501. Moreover, first AlN layer 504 is formed using TMA or TEA as the Al material, NH₃ as the N material, and H₂, N₂, or a mixture thereof as the carrier gas. This corresponds to the step of growing the first nitride semiconductor layer above Si substrate 501 by crystal growth. After that, by maintaining the temperature of Si substrate 501 at 900° C. or higher in an atmosphere in which NH₃ and the carrier gas are supplied, C and Al supplied to the front surface of Si substrate 501 are thermally diffused from the front surface to the back surface of Si substrate 501. This corresponds to the step of maintaining the temperatures of Si substrate 501 and the first nitride semiconductor layer at 900° C. or higher and diffusing the group III metal element from the first nitride semiconductor layer to Si substrate 501. As a result, mixed crystal layer 502 containing Al, Si, and C as main components is formed. The formation of first AlN layer 504 is preferably performed before the thermal diffusion at 900° C. or higher for surface stabilization, and is preferably performed at a temperature that is at least 100° C. lower than the thermal diffusion temperature. From the viewpoint of improving the crystallinity, the film thickness of first AlN layer 504 is preferably at most 10 nm. The highest value of the C concentration in mixed crystal layer 502 can be controlled by the supply amount of the C material. The concentration of the transition metal element in mixed crystal layer 502 can be controlled by, for example, autodoping control by the atmosphere in the reaction furnace such as the growth temperature, growth pressure, and carrier gas flow rate, in addition to intentional doping control by the supply amount of Cp₂Fe which is a Fe material.

After that, the temperature of Si substrate 501 is increased to the growth temperature of second AlN layer 505, for example, 1000° C. or higher, and TMA or TEA is supplied as an Al material, NH₃ is supplied as a N material, and H₂, N₂ or a mixture thereof is supplied as a carrier gas. This corresponds to the step of growing the second nitride semiconductor layer (nitride semiconductor epitaxial layer) above the first nitride semiconductor layer by crystal growth. With this, second AlN layer 505 is formed.

In such a manner, the configuration of nitride semiconductor epitaxial substrate 500 according to Variation 1 of Embodiment 1 can be produced.

As described above, with the method for producing nitride semiconductor epitaxial substrate 500 according to the present embodiment, AlN layer 503 with excellent crystallinity is achieved. Nitride semiconductor epitaxial substrate 500 according to the present embodiment includes Si substrate 501 and AlN layer 503 as described above (an example of a nitride semiconductor epitaxial layer) above Si substrate 501. In other words, as in the present embodiment, a method of producing nitride semiconductor epitaxial substrate 500 in which a layer with excellent crystallinity is disposed above Si substrate 501 is achieved.

(Variation 2 of Embodiment 1)

Next, nitride semiconductor epitaxial substrate 500a according to Variation 2 of Embodiment 1 will be described with reference to FIG. 6B. Nitride semiconductor epitaxial substrate 500a includes a configuration identical to the configuration of nitride semiconductor epitaxial substrate 500 according to Variation 1, except that the configuration of AlN layer 503a, which is an example of a nitride semiconductor epitaxial layer, differs from AlN layer 503 according to Variation 1.

[Configuration]

FIG. 6B is a cross-sectional view of nitride semiconductor epitaxial substrate 500a according to Variation 2 of Embodiment 1 of the present disclosure. As illustrated in FIG. 6B, in the present variation, AlN layer 503a, which is an example of a nitride semiconductor epitaxial layer, is epitaxially grown above Si substrate 501 via mixed crystal layer 502 containing Al, Si and C as main components. In a similar manner to mixed crystal layer 102 according to Embodiment 1, mixed crystal layer 502 has a C concentration of at least 1.0×10⁺²¹ cm⁻³, and a Fe concentration of at most 5.0×10⁺¹⁶ cm⁻³. AlN layer 503a includes first AlN layer 504a and second AlN layer 505a. The C concentration in first AlN layer 504a is higher than the C concentration in second AlN layer 505a. Moreover, first AlN layer 504a has a C concentration distribution in which the C concentration in first AlN layer 504a gradually decreases from the mixed crystal layer 502 side toward the second AlN layer 505a side.

In a similar manner to Variation 1 of Embodiment 1, control of the growth temperature, for example, sets first AlN layer 504a to have a C concentration of 1.0×10⁺¹⁹ cm⁻³, and sets second AlN layer 505a to have a C concentration of 1.0×10⁺¹⁶ cm⁻³. Here, by changing the growth conditions while growing first AlN layer 504a without interrupting the growth, the concentration distribution is achieved in which the C concentration in first AlN layer 504a decreases gradually.

As described above, in the present variation, the initial layer of AlN layer 503a (that is, first AlN layer 504a) is made of AlN with a high concentration of C, and the C concentration is gradually changed from mixed crystal layer 502 toward the AlN layer with a low C concentration (second AlN layer 505a) disposed above first AlN layer 504a. With this, nitride semiconductor epitaxial substrate 500a is provided in which no low-resistance layer is disposed at the interface between AlN layer 503a (more specifically, first AlN layer 504a) and mixed crystal layer 502, and which includes a surface with excellent flatness and a small number of defects.

In addition, a power transistor produced using nitride semiconductor epitaxial substrate 500a has a reduced leak current, and has a reduced number of defects, thereby improving the yield. Moreover, by growing the initial layer of AlN layer 503a at a low temperature, it is possible to achieve nitride semiconductor epitaxial substrate 500a with high reproducibility and excellent productivity.

[Producing Method]

Here, a producing method relating to nitride semiconductor epitaxial substrate 500a according to Variation 2 of Embodiment 1 will be specifically described with reference to FIG. 6B.

Si substrate 501 is set in a MOCVD furnace, and is heated to 500° C. or higher. After that, the C material and Al material are supplied to the front surface of Si substrate 501 at a temperature of 500° C. or higher. For example, TMA, TEA, CBr₄ or C₃H₈ can be used as the C material. TMA or TEA is used as the Al material. The above-described C material and Al material are supplied to the front surface of Si substrate 501 while H₂, N₂ or a mixture thereof is used as a carrier gas. Moreover, TMA or TEA is used as an Al material, NH₃ is used as a N material, and H₂, N₂ or a mixture thereof is used as a carrier gas to form first AlN layer 504a. After that, the temperature of Si substrate 501 is increased to and maintained at 900° C. or higher, so that the C and Al supplied to the front surface of Si substrate 501 are thermally diffused from the front surface of Si substrate 501 toward the back surface of Si substrate 501. With this, mixed crystal layer 502 containing Al, Si and C as main components is formed. During the thermal diffusion, NH₃, TMA or TEA, and carrier gas are continuously supplied. With this, the thermal diffusion step can be performed without interrupting the formation of first AlN layer 504a. Accordingly, it is possible to achieve a C concentration distribution in which the C concentration in first AlN layer 504a gradually decreases from the mixed crystal layer 502 side toward the second AlN layer 505a side. The highest value of the C concentration in mixed crystal layer 502 can be controlled by the supply amount of the C material. The concentration of the transition metal element in mixed crystal layer 502 can be controlled by, for example, autodoping control by the atmosphere in the reaction furnace such as the growth temperature, growth pressure, and carrier gas flow rate, in addition to intentional doping control by the supply amount of Cp₂Fe which is a Fe material.

After that, the temperature of Si substrate 501 is increased to the growth temperature of second AlN layer 505a, for example, 1000° C. or higher, and TMA or TEA is supplied as an Al material, NH₃ is supplied as a N material, and H₂, N₂ or a mixture thereof is supplied as a carrier gas. With this, second AlN layer 505a is formed. In such a manner, the configuration of nitride semiconductor epitaxial substrate 500a according to Variation 2 of Embodiment 1 can be produced.

### Embodiment 2

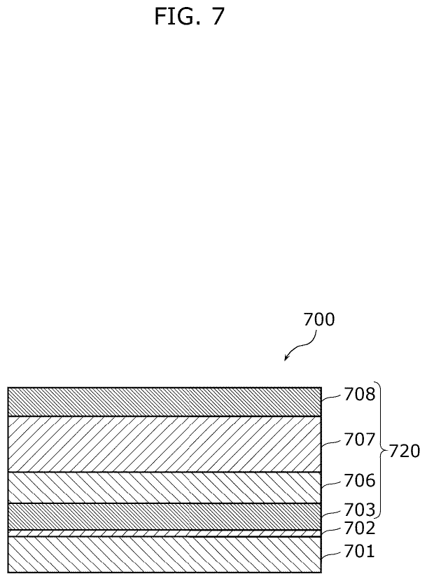

In order to utilize a nitride semiconductor epitaxial substrate with excellent crystallinity as a semiconductor device, it is necessary to form, above the nitride semiconductor epitaxial substrate, a heterostructure epitaxial layer according to the purpose. In the present disclosure, a nitride semiconductor epitaxial substrate including a heterostructure epitaxial layer is specifically referred to as a nitride semiconductor heterostructure epitaxial substrate. A specific example of the nitride semiconductor heterostructure epitaxial substrate utilized in a power transistor will be described below. Here, nitride semiconductor heterostructure epitaxial substrate 700 according to Embodiment 2, which is an example of a nitride semiconductor epitaxial substrate, will be described with reference to FIG. 7.

FIG. 7 is a cross-sectional view of nitride semiconductor heterostructure epitaxial substrate 700 according to Embodiment 2 of the present disclosure.

Nitride semiconductor heterostructure epitaxial substrate 700 according to the present embodiment includes Si substrate 701 having a configuration identical to the configuration of Si substrate 101 according to Embodiment 1. Nitride semiconductor heterostructure epitaxial substrate 700 also includes mixed crystal layer 702 which differs from mixed crystal layer 102 according to Embodiment 1 only in the C concentration. Moreover, in the present embodiment, AlN layer 703, which is an example of a nitride semiconductor epitaxial layer, buffer layer 706 including a single layer or a plurality of layers of AlₓGa₁₋ₓN (0≤x≤1), GaN channel layer 707, and AlGaN barrier layer 708 are epitaxially grown as a heterostructure above Si substrate 701 via mixed crystal layer 702 containing Al, Si, and C as main components. In other words, heterostructure epitaxial layer 720 included in nitride semiconductor heterostructure epitaxial substrate 700 according to the present embodiment includes AlN layer 703, buffer layer 706, GaN channel layer 707 and AlGaN barrier layer 708. Moreover, heterostructure epitaxial layer 720 is disposed above and in contact with mixed crystal layer 702, and is formed by stacking AlN layer 703, buffer layer 706, GaN channel layer 707, and AlGaN barrier layer 708 in this order. When buffer layer 706 includes a plurality of layers of AlₓGa₁₋ₓN (0≤x≤1), the value of x may be different for each layer. In the present embodiment, GaN channel layer 707 is an example of a third nitride semiconductor layer disposed above the nitride semiconductor epitaxial layer (AlN layer 703). AlGaN barrier layer 708 is an example of a fourth nitride semiconductor layer disposed above the third nitride semiconductor layer (GaN channel layer 707). Moreover, at the interface between GaN channel layer 707 and AlGaN barrier layer 708, a high-concentration two-dimensional electron gas is formed due to the effects of piezoelectric polarization and spontaneous polarization. In other words, nitride semiconductor heterostructure epitaxial substrate 700 according to the present embodiment includes two-dimensional electron gas at the interface between the third nitride semiconductor layer and the fourth nitride semiconductor layer. Buffer layer 706 is doped with C at a maximum of 1.0×10⁺²⁰ cm⁻³, so that buffer layer 706 has a high resistance. The C concentration in buffer layer 706 described above is the maximum C concentration in heterostructure epitaxial layer 720.

The C concentration in mixed crystal layer 702 according to the present embodiment is higher than the C concentration in each of the layers included in heterostructure epitaxial layer 720. As described above, the layers included in heterostructure epitaxial layer 720 are AlN layer 703, buffer layer 706, GaN channel layer 707, and AlGaN barrier layer 708. In other words, the C concentration in mixed crystal layer 702 is higher than the C concentration in any of AlN layer 703, buffer layer 706, GaN channel layer 707, and AlGaN barrier layer 708. The C concentration in each of AlN layer 703, buffer layer 706, GaN channel layer 707, and AlGaN barrier layer 708 is defined as the highest value of the C concentration in each layer.

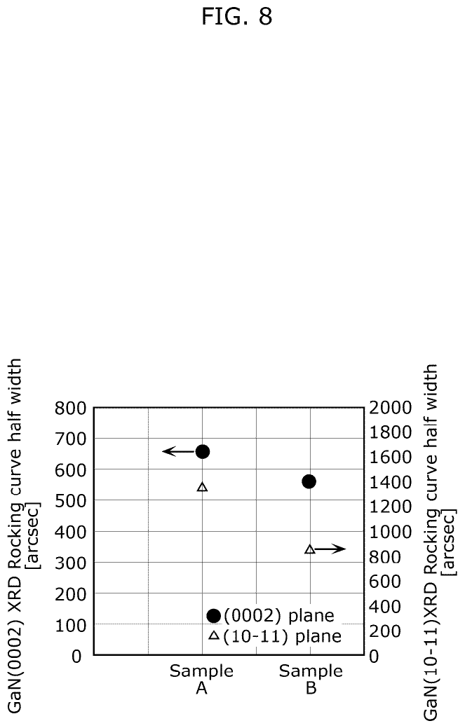

The result of examining the influences of the relationship between the highest C concentration in mixed crystal layer 702 and the highest C concentration in buffer layer 706 on the crystallinity of GaN channel layer 707 will be described below. The crystallinity of GaN channel layer 707 was evaluated by the half widths of the XRD rocking curves of (0002) plane and (10-11) plane. The results are illustrated in FIG. 8. FIG. 8 illustrates the evaluation results of the influences of the C concentration in mixed crystal layer 702 and the C concentration in heterostructure epitaxial layer 720 on the crystallinity of GaN channel layer 707. Here, FIG. 8 illustrates the crystallinity evaluation results of sample A and sample B in which the maximum value of the C concentration in buffer layer 706 was 1.0×10⁺²⁰ cm⁻³, and the C concentration in mixed crystal layer 702 was 1.5×10⁺¹⁸ cm⁻³ and 1.8×10⁺²¹ cm⁻³, respectively. More specifically, sample A is a nitride semiconductor heterostructure epitaxial substrate according to Comparative Example 1. Sample A includes a configuration identical to the configuration of nitride semiconductor heterostructure epitaxial substrate 700 according to the present embodiment, except that the C concentration in the mixed crystal layer included in sample A is different from the C concentration in mixed crystal layer 702 according to the present embodiment. Sample B refers to nitride semiconductor heterostructure epitaxial substrate 700 according to the present embodiment.

As can be seen from FIG. 8, both the half width of (0002) plane and the half width of (10-11) plane were greatly improved in Sample B in which the C concentration in mixed crystal layer 702 was sufficiently higher than the C concentration in buffer layer 706. In the present embodiment, buffer layer 706 is doped with a high concentration of C in order to increase the resistance of buffer layer 706, but the C concentration may be lower than this example for applications that do not require buffer layer 706 to have a high resistance.

The crystallinity of GaN channel layer 707 tends to improve when the C concentration in buffer layer 706 is low. Accordingly, when the C concentration in mixed crystal layer 702 is higher than the C concentration in buffer layer 706, the crystallinity of GaN channel layer 707 is effectively improved. In the present embodiment, the transition metal element concentration in mixed crystal layer 702 is at most 5.0×10⁺¹⁶ cm⁻³.

By forming heterostructure epitaxial layer 720 with mixed crystal layer 702 mainly containing Al, Si and C as a buffer layer as described above, nitride semiconductor heterostructure epitaxial substrate 700 can be achieved in which the active layer (here, GaN channel layer 707) has excellent crystallinity.

In summary, nitride semiconductor heterostructure epitaxial substrate 700 is an example of a nitride semiconductor epitaxial substrate. The C concentration in mixed crystal layer 702 is higher than the C concentration in each layer included in heterostructure epitaxial layer 720, and the transition metal element concentration in mixed crystal layer 702 is at most 5.0×10⁺¹⁶ cm⁻³. Accordingly, the active layer (here, GaN channel layer 707) disposed above mixed crystal layer 702 has excellent crystallinity. In other words, as in the present embodiment, a nitride semiconductor epitaxial substrate (nitride semiconductor heterostructure epitaxial substrate 700) in which a layer with excellent crystallinity is disposed above Si substrate 701 is achieved.

In addition, by forming a power transistor including nitride semiconductor heterostructure epitaxial substrate 700 with excellent crystallinity, device breakdown caused by crystal defects is reduced, and a nitride semiconductor device with excellent reliability is achieved.

### Embodiment 3

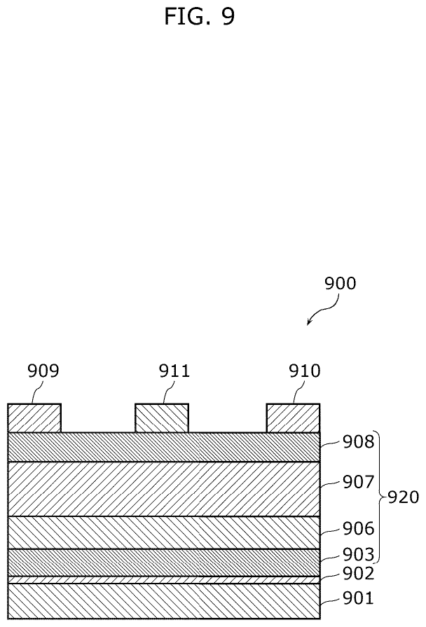

Next, nitride semiconductor device 900 according to Embodiment 3 will be described with reference to FIG. 9. Nitride semiconductor device 900 is an example of a semiconductor device including a nitride semiconductor heterostructure epitaxial substrate.

FIG. 9 is a cross-sectional view of nitride semiconductor device 900 according to Embodiment 3 of the present disclosure. Nitride semiconductor device 900 according to the present embodiment includes Si substrate 901 and mixed crystal layer 902 having configurations identical to the configuration of Si substrate 701 and mixed crystal layer 702 according to Embodiment 2.

Moreover, in the present embodiment, AlN layer 903, buffer layer 906 including a single layer or a plurality of layers of AlₓGa₁₋ₓN (0≤x≤1), GaN channel layer 907, and AlGaN barrier layer 908 are epitaxially grown as a heterostructure above Si substrate 901 via mixed crystal layer 902 containing Al, Si, and C as main components. In other words, heterostructure epitaxial layer 920 included in nitride semiconductor device 900 according to the present embodiment includes AlN layer 903, buffer layer 906, GaN channel layer 907, and AlGaN barrier layer 908. Moreover, heterostructure epitaxial layer 920 is disposed above and in contact with mixed crystal layer 902, and is formed by stacking AlN layer 903, buffer layer 906, GaN channel layer 907, and AlGaN barrier layer 908 in this order. When buffer layer 906 includes a plurality of layers of AlₓGa₁₋ₓN (0≤x≤1), the value of x may be different for each layer. At the interface between GaN channel layer 907 and AlGaN barrier layer 908, a high-concentration two-dimensional electron gas is formed by the effects of piezoelectric polarization and spontaneous polarization. Mixed crystal layer 902 is higher in C concentration than any layers included in heterostructure epitaxial layer 920. In other words, the C concentration in mixed crystal layer 902 according to the present embodiment is higher than the C concentration in each of the layers included in heterostructure epitaxial layer 920. For example, buffer layer 906 is doped with C at a maximum of 1.0×10⁺²⁰ cm⁻³, the C concentration in mixed crystal layer 902 is at least 1.0×10⁺²¹ cm⁻³, and the transition metal element concentration in mixed crystal layer 902 is at most 5.0×10⁺¹⁶ cm⁻³.

Nitride semiconductor device 900 according to the present embodiment further includes gate electrode 911, source electrode 909, and drain electrode 910. More specifically, source electrode 909 and drain electrode 910 are disposed apart from each other above AlGaN barrier layer 908 so as to sandwich gate electrode 911. In other words, nitride semiconductor device 900 according to the present embodiment is a semiconductor device including a nitride semiconductor epitaxial substrate in which a layer with excellent crystallinity is disposed above Si substrate 901.

In such a manner, by forming a power transistor using a nitride semiconductor heterostructure epitaxial substrate with excellent crystallinity, device breakdown caused by crystal defects is reduced, and nitride semiconductor device 900 with excellent reliability is achieved.

### Other Embodiments

Although the embodiments have been described above, the present disclosure is not limited to the above embodiments.

In addition, a form obtained by making various modifications conceivable by those skilled in the art to each embodiment, and a form realized by arbitrarily combining the structural components and functions in each embodiment without departing from the gist of the present disclosure are also included in the present disclosure.

### INDUSTRIAL APPLICABILITY

The present disclosure realizes a high-quality nitride semiconductor epitaxial substrate, improves the performance of a nitride semiconductor device including the nitride semiconductor epitaxial substrate, and achieves a longer life of the device.

1. A nitride semiconductor epitaxial substrate comprising:
a Si substrate;
a nitride semiconductor epitaxial layer disposed above the Si substrate; and
a mixed crystal layer disposed between the Si substrate and the nitride semiconductor epitaxial layer, the mixed crystal layer containing Si and a group III metal element, the mixed crystal layer containing a high concentration of C,
wherein a concentration of the C in the mixed crystal layer is at least 1.0×10⁺²¹ cm⁻³, and
the mixed crystal layer contains a transition metal element at a concentration of at most 5.0×10⁺¹⁶ cm⁻³.

2. The nitride semiconductor epitaxial substrate according to claim 1,
wherein the transition metal element is at least one of Fe, Cr, Cu, Ni, Mn, or Co.

3. The nitride semiconductor epitaxial substrate according to claim 1,
wherein the transition metal element is at least one of Fe, Cr, Cu, Ni, Mn, or Co, and
a concentration of each of a plurality of transition metal elements in the mixed crystal layer is at most 5.0×10⁺¹⁶ cm⁻³, the plurality of transition metal elements each being the transition metal element.

4. The nitride semiconductor epitaxial substrate according to claim 1,
wherein the group III metal element is identical to a group III metal element contained in the nitride semiconductor epitaxial layer.

5. The nitride semiconductor epitaxial substrate according to claim 1,
wherein the mixed crystal layer has a C concentration distribution in which the concentration of the C is higher on a nitride semiconductor epitaxial layer side and is lower on a Si substrate side, the concentration of the C gradually decreasing from the nitride semiconductor epitaxial layer side toward the Si substrate side.

6. The nitride semiconductor epitaxial substrate according to claim 1,
wherein the mixed crystal layer has a thickness of at most 50 nm.

7. The nitride semiconductor epitaxial substrate according to claim 1,
wherein the concentration of the C in the mixed crystal layer is at most 1.0×10⁺²² cm⁻³.

8. The nitride semiconductor epitaxial substrate according to claim 1,
wherein the nitride semiconductor epitaxial layer includes an AlN layer on a mixed crystal layer side.

9. The nitride semiconductor epitaxial substrate according to claim 1,
wherein the nitride semiconductor epitaxial layer includes a first nitride semiconductor layer and a second nitride semiconductor layer, and
the first nitride semiconductor layer contains C at a concentration that is higher than a concentration of C in the second nitride semiconductor layer.

10. A nitride semiconductor epitaxial substrate comprising:
a Si substrate;
a heterostructure epitaxial layer which includes a nitride semiconductor epitaxial layer disposed above the Si substrate; and
a mixed crystal layer disposed between the Si substrate and the nitride semiconductor epitaxial layer, the mixed crystal layer containing Si and a group III metal element, the mixed crystal layer containing a high concentration of C,
wherein a concentration of the C in the mixed crystal layer is higher than a concentration of C in each of layers included in the heterostructure epitaxial layer, and
the mixed crystal layer contains a transition metal element at a concentration of at most 5.0×10⁺¹⁶ cm⁻³.

11. The nitride semiconductor epitaxial substrate according to claim 1, further comprising:
a third nitride semiconductor layer disposed above the nitride semiconductor epitaxial layer;
a fourth nitride semiconductor layer disposed above the third nitride semiconductor layer; and
a two-dimensional electron gas at an interface between the third nitride semiconductor layer and the fourth nitride semiconductor layer.

12. A nitride semiconductor device formed using the nitride semiconductor epitaxial substrate according to claim 11.

13. A method for producing a nitride semiconductor epitaxial substrate, the method comprising:
increasing a temperature of a Si substrate to 500° C. or higher;
supplying a C material to a surface of the Si substrate;
growing a first nitride semiconductor layer above the Si substrate by crystal growth;
maintaining the temperature of the Si substrate and a temperature of the first nitride semiconductor layer at 900° C. or higher, and diffusing a group III metal element from the first nitride semiconductor layer to the Si substrate; and
growing a second nitride semiconductor layer above the first nitride semiconductor layer by crystal growth.

14. The method for producing the nitride semiconductor epitaxial substrate according to claim 13,
wherein the C material is one of trimethylaluminum, triethylaluminum, carbon tetrabromide, or propane.
